(19) United States
(12) Patent Application Publication
(10) Pub. No.: US 2019/0077937 A1
(43) Pub. Date: Mar. 14, 2019

(54) ULTRASONIC MASKING MATERIAL, IN PARTICULAR FOR WEAPON SYSTEM

(71) Applicant: MBDA FRANCE, Le Plessis-Robinson (FR)

(72) Inventor: René Dupré, Le Plessis-Robinson (FR)

(73) Assignee: MBDA FRANCE, Le Plessis-Robinson (FR)

(21) Appl. No.: 16/084,536

(22) PCT Filed: Mar. 3, 2017
(86) PCT No.: PCT/FR2017/000038

§ 371 Date: Sep. 12, 2018

(30) Foreign Application Priority Data
Mar. 15, 2016 (FR) 1600425

(51) Int. Cl. C08K 7/28; C08L 63/00; H01L 23/29; H01L 23/00

(52) U.S. Cl. CPC C08K 7/28; C08L 63/00; C08L 2205/20; H01L 23/573; H01L 23/293

(57) ABSTRACT

An ultrasonic masking system (1) comprises at least one resin (2) and a plurality of hollow spheres (4) embedded in the resin (2), forming a coating material having a reduced mass capable of hindering an analysis by ultrasonic detection.

The present invention relates to an ultrasonic masking material intended to cover at least one electronic component of an electronic device, in particular a weapon system such as a missile for example.

In the scope of the present invention:
an electronic device comprises at least one electronic component and is intended to implement at least one electronic function. This electronic device can, in particular, correspond to an electronic board which, usually, comprises, in particular, a printed circuit provided with a plurality of electronic components;
an ultrasonic masking material is a material capable of masking (in other words, of misleading) an examination (or analysis) made by ultrasound and more generally hindering such an ultrasound (or ultrasonic) type examination, as specified below.

This masking material has, in particular, the aim of protecting against possible reverse engineering operations which could be perpetrated on an electronic function implemented on an electronic device, in particular an electronic board, as mentioned above.

“Reverse engineering” means any intrusion or any intrusion attempt consisting of a person accessing or attempting to access information stored in an electronic device, particularly with a view to copying it, and more specifically, in the scope of the present invention, an intrusion implemented using an ultrasonic detection.

It is known, that to protect electronic devices against reverse engineering and the prevent competitors, or enemies in the case of military equipment, from accessing the technology stored in the equipment, these devices are often completely surrounded by a coating resin.

Generally, this resin which is coloured, prevents a direct display of the elements covered by said resin.

If an individual all the same wants to try to display the elements thus protected, they will generally try to use non-invasive examination techniques, in particular of the ultrasonic type.

Such an examination is generally carried out using an acoustic microscope and has the aim of producing a map of an electronic function with the aim of retrieving sizing information (positioning, size, shape, number, etc.).

The present invention relates to a coating material which, while being produced easily and at a reduced cost, makes it possible to hinder non-invasive ultrasonic-type examination.

More specifically, the present invention relates to a material referred to as ultrasonic masking material, which comprises at least one resin.

According to the invention, said ultrasonic masking material is noteworthy in that it comprises, in addition, a plurality of hollow spheres embedded in said resin.

Thus, thanks to the invention, a material has been created the resin of which comprises a plurality of delamination zones (no material) at the level of the hollow inner part (void of material) of the hollow spheres embedded in the resin. These delamination zones create a multitude of interfaces which hinder ultrasonic examination using an acoustic microscope.

Thus a (partial or total) zone of an electronic component or even an electronic function can be made unexploitable by an acoustic microscopy system, by encapsulating it by means of said ultrasonic masking material.

In a preferred embodiment, said hollow spheres are substantially evenly distributed in said resin.

Furthermore, advantageously, some of said hollow spheres are made of at least one of the following materials:
glass;
phenolic resin.

In addition, advantageously the hollow spheres comprise an overall diameter of between 20 and 100 μm. Furthermore, in a specific embodiment, the ultrasonic masking material comprises hollow spheres having different diameters.

Moreover, in a specific embodiment, said resin is made of at least one of the following materials: epoxy, polyurethane, phenolic.

The present invention also relates to an electronic device, in particular an electronic board, comprising at least one electronic component.

According to the invention, said electronic device comprises a coating surrounding at least said electronic component, and said coating is made of, at least partially, the ultrasonic masking material specified above, which makes it possible to hinder ultrasonic detection.

Thus a person who plans to carry out reverse engineering on the electronic device, by using ultrasonic detection, is not able to examine the electronic component(s) protected by the coating resin.

The appended figures will make it easy to understand how the invention can be realised. In these figures, identical references mean similar elements.

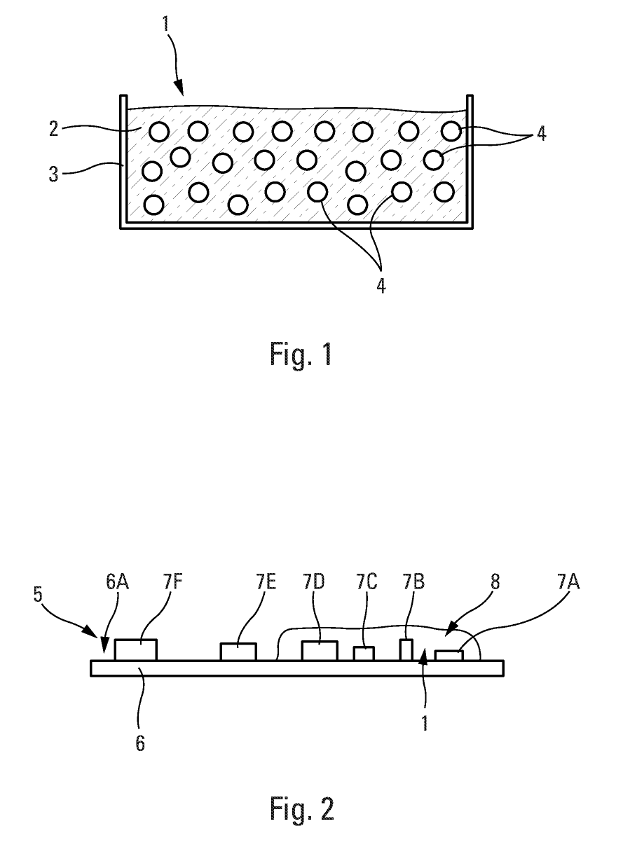

FIG. 1 is a schematic view of an ultrasonic masking material.

FIG. 2 is a schematic, cross-section view of an electronic board, certain electronic components of which are coated with an ultrasonic masking material.

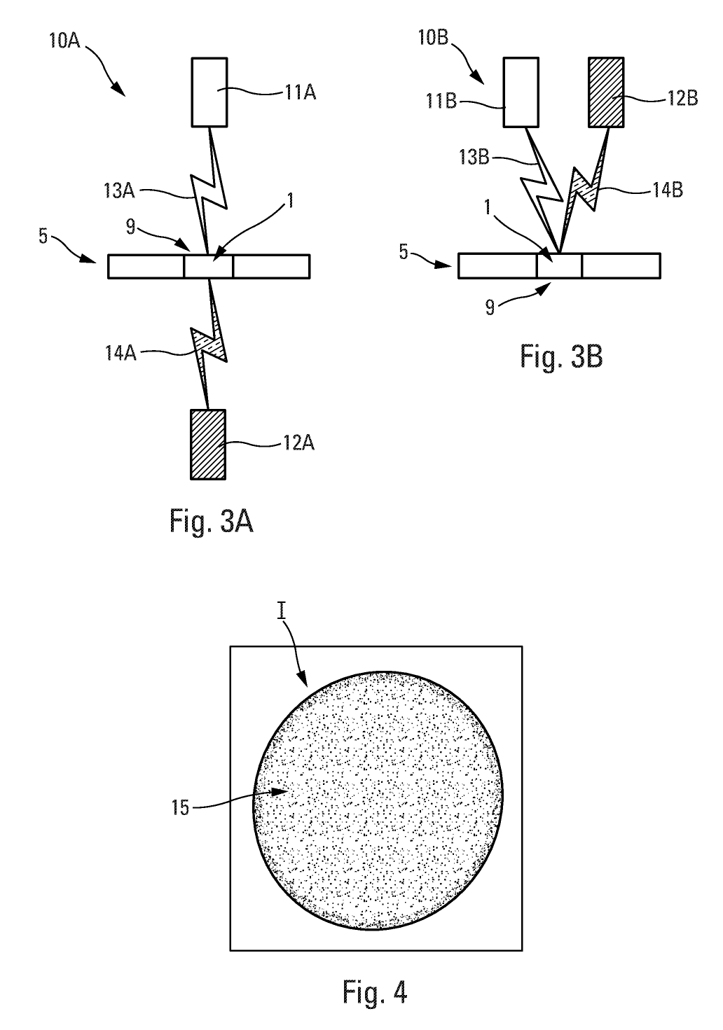

FIGS. 3A and 3B are schematic front views of an ultrasonic detection device, respectively according to two different embodiments.

FIG. 4 is an image obtained by ultrasonic examination on an ultrasonic masking material.

The present invention relates to a coating material intended to hinder an ultrasonic-type examination. More specifically, it relates to a material 1 referred to as ultrasonic masking material, which comprises at least one resin 2, as shown in FIG. 1, on which the resin 2 is inserted into a container 3 shown schematically.

According to the invention, said ultrasonic masking material 1 comprises, in addition, a plurality of hollow spheres 4 embedded in said resin 2, as can be seen in FIG. 1.

“Hollow spheres” means hollow objects of any possible shapes, and preferably spherical, which have no material inside an envelope.

In a preferred embodiment, said hollow spheres 4 are (substantially) evenly distributed in said resin 2.

These hollow spheres 4 can be made of different materials such as glass, phenolic resin, etc. The aim of these hollow spheres 4 is to generate a multitude of zones without material in the material 1.

In a preferred embodiment, the hollow spheres 4 preferably comprise an overall diameter of between 20 and 100 μm. “Overall diameter” of a hollow sphere means the diameter of a sphere wherein said hollow sphere can be fitted.

As an illustration, the concentration of hollow spheres 4 in the material 1 can vary according to, in particular, the diameter of the spheres, the mass of the spheres with respect to that of the resin, etc.

Moreover, in the scope of the present invention, said resin 2 can be made of any families of liquid resins. Preferably, said resin 2 is made of at least one of the following materials: epoxy, polyurethane, phenolic.

Thus a material 1 with a reduced mass is obtained, which, while being produced easily and at a reduced cost as specified below, makes it possible to hinder non-invasive ultrasonic-type examination.

The size of the hollow spheres 4, as well as the distribution thereof and the concentration thereof in the resin 2, is variable and preferably adapted to the application considered of the ultrasonic masking material 1.

The material 1 can, in particular, comprise spheres of different diameters.

A preferred application of said material 1 relates to the coating of electronic component(s) of an electronic device 5.

In FIG. 2, an electronic device 5 has been shown schematically, as an example, here as an electronic board, illustrating this preferred application of the invention.

This electronic device 5 comprises, in the usual fashion:
a printed circuit 6 (circuit printed with connections); and
usual electronic components 7A to 7F, which are arranged on said printed circuit 2 on an upper face 6A of the printed circuit 2. At least some of said electronic components 7A to 7F are made smart by adding at least one program and/or sensitive information.

This electronic device 5 is intended to be mounted in the usual fashion on an item of equipment (not shown), for example a weapon system, in particular missile type. It can contain, in particular, information making it possible to command or control the functioning of the equipment in question, or specific means of the latter.

A zone (or part) of the electronic device 5 provided with electronic components 7A to 7D has been encapsulated by the ultrasonic masking material 1, as defined above, forming a coating 8.

The masking produced by the material 1 therefore aims to prevent the carrying out of an examination using an acoustic microscope.

Moreover, because of the presence of the hollow spheres 4, the mass of the material 1 is reduced with respect to that of the resin 2 by itself.

Furthermore, the material 1 can be produced:
easily, by mixing the hollow spheres 4 in a liquid resin 2, before heating it to make it solid and to obtain the material 1. To do this, the material used for the hollow spheres must have a strength that is sufficient to not be deformed, or at most within acceptable limits, under the effect of the expansion of the air located inside the hollow spheres, when the resin is heated; and
at a reduced cost, by using commercially available spheres at a low cost.

Reverse engineering using ultrasonic detection generally uses an acoustic analysis system (or acoustic microscope) 10A, 10B which is an analysis means capable of revealing the problems of delamination between materials. It also makes it possible to detect the presence of different materials in an assembly, in particular in an electronic device 5 such as illustrated schematically in FIGS. 3A and 3B.

To do this, the electronic device 5 to be analysed is immersed in a coupling liquid (not shown) which enables ultrasonic coupling between an emission probe 11A, 11B, a receiving probe 12A, 12B and a part (or zone) 9 of the electronic device 5 to be analysed.

The principle of the acoustic analysis system 10A, 10B is to generate the ultrasounds 13A, 13B using the emission probe 11A, 11B and to analyse the corresponding signal 14A, 14B received using a receiving probe 12A, 12B. The signals emitted and received are focused by a lens integrated in each probe.

Receiving the signal can be done in two ways:
either by transmission, as shown in FIG. 3A. In this case, the acoustic analysis system 10A analyses the signal received after passage through the part 9 to be analysed;
or by reflection, as shown in FIG. 3B. In this case, the acoustic analysis system 10B analyses the signal sent by the part 9 to be analysed.

The signal emitted by the emission probe (or ultrasonic source) 11A, 11B enters into the part 9 to be analysed. This signal will be modified by passing through various materials constituting this part 9.

The speed and the phase of the signal are modified according to the materials. The signal is modified by the intrinsic properties of the material (density, elasticity, viscosity, porosity, adhesion, etc.).

The acoustic analysis system 10A, 10B compares the signals emitted and received. This analysis makes it possible, after a processing of the signals, to reveal the presence (or not) of various materials or intrinsic irregularities. This is because, each time that the signal passes from one material to another, the transmitted signal is modified. In the case of a homogenous material, there is only one interface, and the signal has only one movement speed. The result of the examination is displayed by the system in a shade of grey or in false colour. A delamination (presence of air between two materials) is displayed by a white colour.

FIG. 4 schematically illustrates an image I obtained by such an acoustic analysis system 10A, 10B, of an ultrasonic masking material 1.

The result obtained is conveyed by an image I that is spotted with marks 15 (white in colour) corresponding to the hollow spheres 4 incorporated within the resin 2, thus making the elements constituting the resin-soaked function with this material 1 non-detectable.

According to the size, the concentration and the distribution of the hollow spheres, a more or less masked material is obtained, which is conveyed by a more or less spotted image.

The ultrasonic masking material 1, as defined above, therefore has, in particular, the following advantages:
a simple production, and at a reduced cost;
a masking with ultrasonic rays; and
a decrease in mass with respect to a resin without hollow spheres.

1. An ultrasonic masking material, comprising:
a resin; and
a plurality of hollow spheres embedded in said resin.

2. The ultrasonic masking material of claim 1, wherein said plurality of hollow spheres are substantially evenly distributed in said resin.

3. The ultrasonic masking material of claim 1, wherein said resin comprises epoxy, polyurethane, phenolic, or any combination thereof.

4. The ultrasonic masking material of claim 1, wherein at least some of said hollow spheres comprise glass, phenolic resin, or any combination thereof.

5. The ultrasonic masking material of claim 1, wherein at least some of said hollow spheres differ in diameter.

6. An electronic board comprising an electronic component surrounded by a coating, the coating at least partially comprising the ultrasonic masking material of claim 1.

7. A weapon system, comprising an electronic board comprising an electronic component surrounded by a coating, the coating at least partially comprising the ultrasonic masking material of claim 1.
